(19) United States
(12) Patent Application Publication
(10) Pub. No.: US 2025/0048804 A1
(43) Pub. Date: Feb. 6, 2025

(54) LIGHT-EMITTING DEVICE, PLANAR LIGHT SOURCE, AND LIQUID CRYSTAL DISPLAY DEVICE

(71) Applicant: NICHIA CORPORATION, Tokushima (JP)

(72) Inventor: Hiroyuki TAKASHIMA, Itano-gun (JP)

(73) Assignee: NICHIA CORPORATION, Tokushima (JP)

(21) Appl. No.: 18/788,037

(22) Filed: Jul. 29, 2024

(30) Foreign Application Priority Data
Aug. 4, 2023 (JP) 2023-127911

(51) Int. Cl. H01L 33/54; G02F 1/13357; H01L 25/075; H01L 33/50

(52) U.S. Cl. CPC H01L 33/54; G02F 1/133603; G02F 1/133606; H01L 25/0753; H01L 33/502

(57) ABSTRACT

A light-emitting device includes A light-emitting device according to one embodiment of the present disclosure includes: a support body including a wall portion, a main surface surrounded by the wall portion, and a recessed portion defined by the wall portion and the main surface; a light-emitting element mounted on the main surface; and a light-transmissive member disposed on the wall portion and the light-emitting element. An upper surface of the light-transmissive member includes a first surface, a second surface surrounded by the first surface in a plan view and protruding upward relative to the first surface in a cross-sectional view, and a third surface having a curved shape and connecting the first surface and the second surface in a cross-sectional view. An upper surface of the wall portion includes a first inclined surface inclined with respect to the main surface. The third surface is located above the first inclined surface.

### CROSS REFERENCE TO RELATED APPLICATION

This application claims priority to Japanese Patent Applications No. 2023-127911, filed on Aug. 4, 2023, and the entire contents of which are hereby incorporated by reference.

### BACKGROUND

### Technical Field

The present disclosure relates to a light-emitting device, a planar light source, and a liquid crystal display device.

### Background Art

As a light-emitting device that can control light distribution, for example, a light-emitting device is known that includes a support body including a wall portion, a light-emitting element placed on the support body and surrounded by the wall portion in a plan view, a first light-transmissive member covering the light-emitting element and the wall portion, and a light-shielding member covering the first light-transmissive member (for example, see WO 2022/196300).

### SUMMARY

The present disclosure provides a light-emitting device having narrow light distribution characteristics.

A light-emitting device according to one embodiment of the present disclosure includes: a support body including a wall portion, a main surface surrounded by the wall portion, and a recessed portion defined by the wall portion and the main surface; a light-emitting element mounted on the main surface; and a light-transmissive member disposed on the wall portion and the light-emitting element. An upper surface of the light-transmissive member includes a first surface, a second surface surrounded by the first surface in a plan view and protruding upward relative to the first surface in a cross-sectional view, and a third surface having a curved shape and connecting the first surface and the second surface in a cross-sectional view. An upper surface of the wall portion includes a first inclined surface inclined with respect to the main surface. The third surface is located above the first inclined surface.

According to one embodiment of the present disclosure, a light-emitting device having narrow light distribution characteristics can be provided.

### BRIEF DESCRIPTION OF DRAWINGS

FIG. 1 is a schematic top view exemplifying a light-emitting device according to a first embodiment.

FIG. 2 is a schematic cross-sectional view taken along line II-II in FIG. 1.

FIG. 3 is a schematic top view in which a first light-transmissive member and a second light-transmissive member are omitted from the light-emitting device illustrated in FIG. 1.

FIG. 4 is a schematic top view illustrating leads of the light-emitting device illustrated in FIG. 1.

FIG. 5 is a schematic bottom view of the light-emitting device illustrated in FIG. 1.

FIG. 6 is a schematic top view exemplifying a light-emitting device according to a first modified example of the first embodiment.

FIG. 7 is a schematic cross-sectional view taken along line VII-VII illustrated in FIG. 6.

FIG. 8 is a schematic cross-sectional view exemplifying a light-emitting device according to a second modified example of the first embodiment.

FIG. 9 is a schematic cross-sectional view exemplifying a light-emitting device according to a third modified example of the first embodiment.

FIG. 10 is a schematic cross-sectional view exemplifying a light-emitting device according to a fourth modified example of the first embodiment.

FIG. 11 is a schematic cross-sectional view exemplifying a light-emitting device according to a fifth modified example of the first embodiment.

FIG. 12 is a schematic cross-sectional view exemplifying a light-emitting device according to a sixth modified example of the first embodiment.

FIG. 13 is a schematic top view illustrating a planar light source according to the first embodiment.

FIG. 14 is a schematic cross-sectional view taken along line XIV-XIV in FIG. 13.

FIG. 15 is a schematic partial cross-sectional view illustrating the planar light source including a demarcating member.

FIG. 16 is a configuration view exemplifying a liquid crystal display device according to a second embodiment.

### DETAILED DESCRIPTION

Hereinafter, embodiments for carrying out the invention will be described with reference to the drawings. Note that, in the following description, terms indicating a specific direction or position (e.g., “upper”, “lower”, and other terms including those terms) are used as necessary. The use of those terms is to facilitate understanding of the invention with reference to the drawings, and the technical scope of the present invention is not limited by the meanings of those terms. Parts having the same reference signs appearing in a plurality of drawings indicate identical or equivalent parts or members.

Further, the following embodiments exemplify light-emitting devices and the like for embodying the technical idea of the present invention, and the present invention is not limited to the description below. The dimensions, materials, shapes, relative arrangements, and the like of constituent components described below are not intended to limit the scope of the present invention to those alone, but are intended to provide an example, unless otherwise specified. The contents described in one embodiment can be applied to the other embodiment and modified examples. The sizes, positional relationship, and the like of the members illustrated in the drawings can be exaggerated in order to clarify the explanation. Furthermore, in order to avoid excessive complication of the drawings, a schematic view in which some elements are not illustrated may be used, or an end view illustrating only a cutting surface may be used as a cross-sectional view. Further, in the present specification, the term “parallel” includes a deviation of about +5° from being parallel.

### First Embodiment

### [Light-Emitting Device 20]

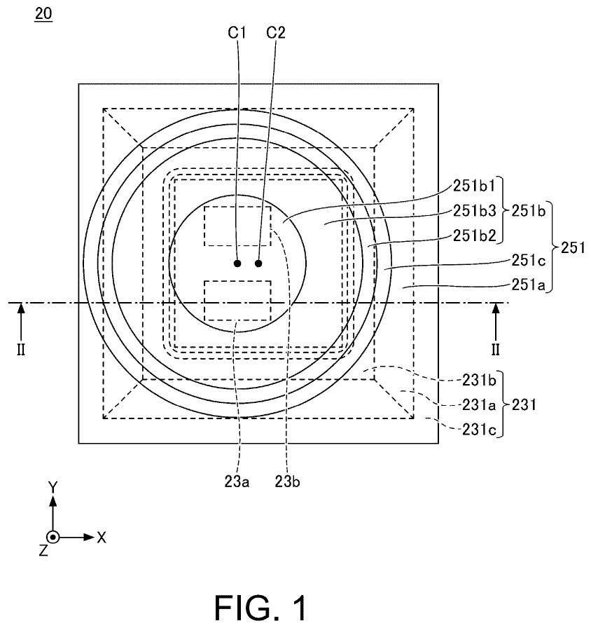

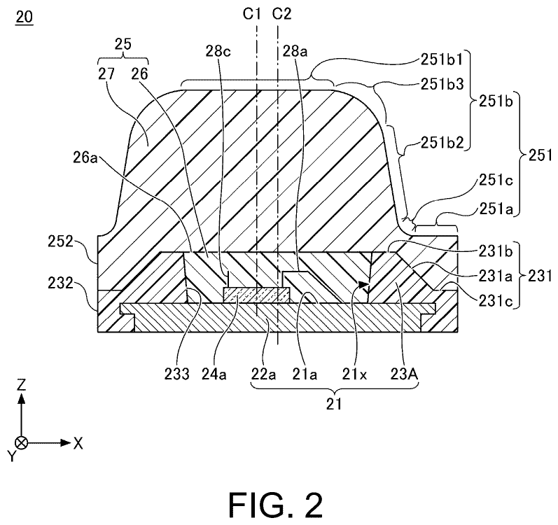

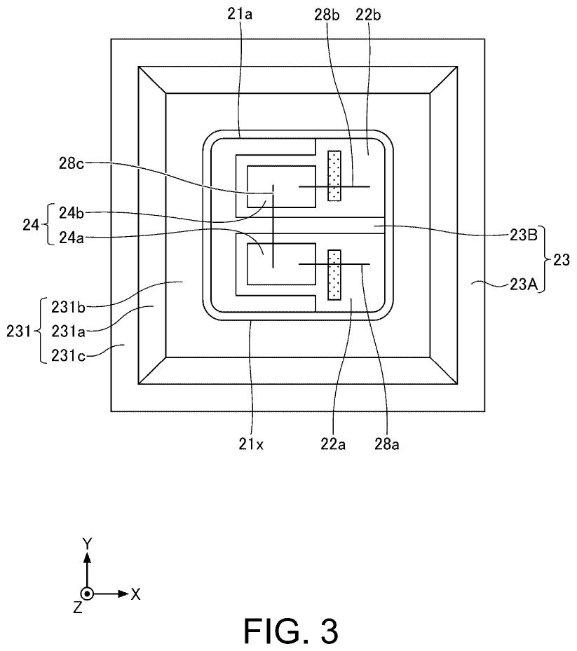

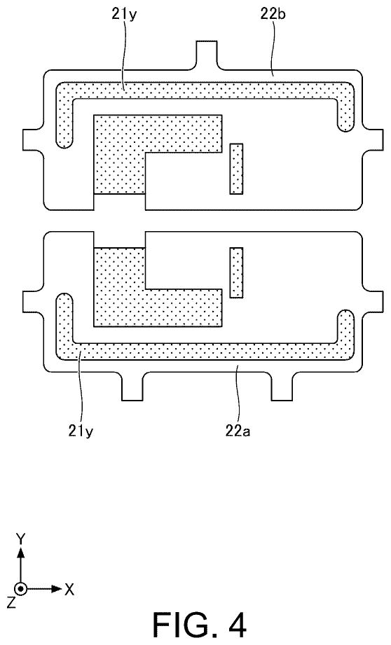

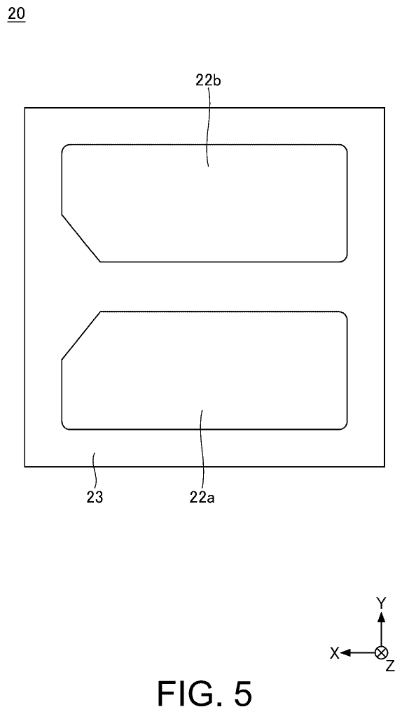

FIG. 1 is a schematic top view exemplifying a light-emitting device according to a first embodiment. FIG. 2 is a schematic cross-sectional view taken along line II-II in FIG. 1. FIG. 3 is a schematic top view showing the light-emitting device illustrated in FIG. 1. In FIG. 3, a first light-transmissive member and a second light-transmissive member in FIG. 1 are omitted. FIG. 4 is a schematic top view illustrating leads of the light-emitting device illustrated in FIG. 1. FIG. 5 is a schematic bottom view of the light-emitting device illustrated in FIG. 1. Note that, the X direction and/or the Y direction illustrated in each drawing may be referred to as a lateral direction, the Z direction may be referred to as a vertical direction, and a direction from the −Z side toward the +Z side may be referred to as an upward direction. Further, an expression of “in a plan view” as used in the present specification indicates a case when viewed downward from the +Z side.

As illustrated in FIG. 1 to FIG. 5, a light-emitting device 20 includes a support body 21, at least one light-emitting element 24, and a light-transmissive member 25.

The support body 21 includes a wall portion 23A, a main surface 21a surrounded by the wall portion 23A, and a recessed portion 21x defined by the wall portion 23A and the main surface 21a. The light-emitting element 24 is mounted on the main surface 21a. The light-transmissive member 25 is disposed on the wall portion 23A and the light-emitting element 24. In the example illustrated in FIG. 2, the main surface 21a is a flat surface.

The light-transmissive member 25 includes an upper surface 251 and lateral surfaces 252 each connected to the upper surface 251. The upper surface 251 includes a first surface 251a, a second surface 251b that is surrounded by the first surface 251a in a plan view and protrudes upward relative to the first surface 251b in a cross-sectional view, and a third surface 251c having a curved shape that connects the first surface 251a and the second surface 251b in a cross-sectional view. In the example illustrated in FIG. 2, the first surface 251a is a flat surface parallel to the main surface 21a. The curvature radius of the third surface 251c is 0.05 mm or more and 0.15 mm or less, for example.

The wall portion 23A has an upper surface 231 and outer lateral surfaces 232 each connected to a corresponding one of the upper surface 231. Further, the wall portion 23A has inner lateral surfaces 233 connecting a corresponding one of the upper surface 231 and the main surface 21a. The recessed portion 21x is defined by the main surface 21a and the inner lateral surfaces 233 of the wall portion 23A. The upper surface 231 surrounds the main surface 21a in a plan view. The upper surface 231 includes first inclined surfaces 231a that are inclined with respect to the main surface 21a. The first inclined surfaces 231a are inclined downward with increasing proximity to the outer side of the support body 21. The inclination angle of the first inclined surfaces 231a with respect to the main surface 21a is 45 degrees, for example. The third surface 251c included in the upper surface 251 of the light-transmissive member 25 is located above the first inclined surfaces 231a. In the example illustrated in FIG. 1 to FIG. 5, the upper surface 231 of the wall portion 23A further includes a flat surface 231b connected to the upper side of the first inclined surfaces 231a, and a flat surface 231c connected to the lower side of the first inclined surfaces 231a. In the examples illustrated in FIG. 1 to FIG. 5, the flat surface 231b, the flat surface 231c, and the main surface 21a are parallel to each other. Each of the outer lateral surfaces 232 of the wall portion 23A is located in the same plane as a corresponding one of the lateral surfaces 252 of the light-transmissive member 25, for example. The outer lateral surfaces 232 of the wall portion 23A and the lateral surfaces 252 of the light-transmissive member 25 are, for example, perpendicular to the main surface 21a.

With the light-transmissive member 25 having the second surface 251b protruding upward relative to the first surface 251a, light from the light-emitting elements 24 is refracted and emitted from the second surface 251b. Thus, the light-emitting device can emit light with a narrow light distribution. Further, in the light-emitting device 20, the upper surface 231 of the wall portion 23A includes the first inclined surfaces 231a inclined with respect to the main surface 21a, and the third surface 251c having a curved shape is located above the first inclined surfaces 231a. Accordingly, light having reached the third surface 251c is reflected by the third surface 251c and can reach one of the first inclined surfaces 231a. Then, light having reached the first inclined surface 231a can be emitted from one of the lateral surfaces 252 of the light-transmissive member 25, or can be reflected by the first inclined surface 231a and emitted from one of the lateral surfaces 252 of the light-transmissive member 25. When the light having reached the third surface 251c is reflected by the third surface 251c and is emitted from one of the lateral surfaces 252 of the light-transmissive member 25, the light does not travel in an obliquely upward direction, but can travel in the lateral direction or an obliquely downward direction. Accordingly, light having narrow light distribution characteristics can be emitted from the light-transmissive member 25 without inhibiting narrowing of the light distribution.

The third surface 251c is preferably located on the upper end side of the first inclined surfaces 231a (i.e., the side closer to the flat surface 231b). With this structure, the light reflected by the third surface 251c easily impinges on one of the first inclined surfaces 231a. Accordingly, the light reflected by the third surface 251c is incident on the flat surface 231c of the wall portion 23A. Thus, light emitted obliquely upward from the lateral surface 252 of the light-transmissive member 25 can be reduced, and light emitted laterally or downward from the lateral surface 252 of the light-transmissive member 25 can be increased, which can contribute to the narrowing of the light distribution.

The distance between the first surface 251a and the flat surface 231b in the Z direction is preferably ¼ or more and ⅓ or less of the distance between the first surface 251a and the flat surface 231c in the Z direction. When the distance between the first surface 251a and the flat surface 231b in the Z direction is ¼ or more of the distance between the first surface 251a and the flat surface 231c in the Z direction, a larger amount of light can be transmitted between the first surface 251a and the flat surface 231b. Thus, an amount of the light emitted from the lateral surfaces 252 of the light-transmissive member 25 in the lateral direction or the downward direction increases, which can further contribute to the narrowing of the light distribution. On the other hand, when the distance between the first surface 251a and the flat surface 231b in the Z direction is ⅓ or less of the distance between the first surface 251a and the flat surface 231c in the Z direction, this case can contribute to downsizing of the light-emitting device 20.

In the example illustrated in FIG. 1, the third surface 251c is in a circumference-like shape. As illustrated in FIG. 1, the third surface 251c can contribute to the narrow light distribution, even when the third surface 251c overlaps not entirely with the first inclined surfaces 231a. That is, as long as the third surface 251c is located above the first inclined surfaces 231a in at least one cross section among cross sections intersecting the circumferential direction in which the third surface 251c lies, the third surface 251c can contribute to the narrowing of the light distribution. For example, as illustrated in FIG. 1, when the first inclined surfaces 231a form a rectangular shape in a plan view, portions of the third surface 251c in regions corresponding to four corners of the rectangular shape formed by the first inclined surfaces 231a is not located above the first inclined surfaces 231a, and portions of the third surface 251c in regions between the corners is located above the first inclined surfaces 231a.

In the example illustrated in FIG. 1 to FIG. 5, the light-emitting device 20 further includes leads 22a and 22b, light-emitting elements 24a and 24b, and wires 28a, 28b, and 28c. The light-emitting elements 24a and 24b are disposed on the leads 22a and 22b, respectively.

The support body 21 includes the leads 22a and 22b and a resin member 23. The resin member 23 includes the wall portion 23A and a holding portion 23B that is located between the leads 22a and 22b and holds the leads 22a and 22b. A part of the upper surface of each of the leads 22a and 22b is exposed in the recessed portion 21x, and constitutes a part of the main surface 21a. The leads 22a and 22b are exposed from the wall portion 23A at the lower surface of the light-emitting device 20. The light-emitting element 24a is disposed on the lead 22a exposed from the wall portion 23A. The light-emitting element 24b is disposed on the lead 22b exposed from the wall portion 23A. That is, the light-emitting elements 24a and 24b are disposed at the main surface 21a.

The wire 28a connects the upper surface of the lead 22a and the upper surface of the light-emitting element 24a. The wire 28b connects the upper surface of the lead 22b and the upper surface of the light-emitting element 24b. The wire 28c connects the upper surface of the light-emitting element 24a and the upper surface of the light-emitting element 24b. The light-emitting elements 24a and 24b are connected in series via the wires 28a, 28b, and 28c.

In the example illustrated in FIG. 2, the light-transmissive member 25 is constituted by a first light-transmissive member 26 and a second light-transmissive member 27. The first light-transmissive member 26 is located in the recessed portion 21x of the support body 21. The first light-transmissive member 26 covers the light-emitting elements 24a and 24b, the main surface 21a, and the inner lateral surfaces 233 of the wall portion 23A. An upper surface 26a of the first light-transmissive member 26 is located in the same plane as the flat surface 231b included in the upper surface 231 of the wall portion 23A. The second light-transmissive member 27 is disposed on the upper surface 231 of the wall portion 23A that include the first inclined surfaces 231a and the upper surface 26a of the first light-transmissive member 26. In the example illustrated in FIG. 1, the second surface 251b of the light-transmissive member 25 has a circular shape in a plan view.

In FIG. 1 and FIG. 2, “C1” indicates the center of the light-emitting element 24 and the center of the second surface 251b. Further, “C2” indicates the center of the main surface 21a. In the example illustrated in FIG. 1 and FIG. 2, the center of the light-emitting element 24 is different from the center of the main surface 21a, and coincides with the center of the second surface 251b. The center of the light-emitting element 24 is different from the center of the main surface 21a, so as to reliably dispose the wires 28a to 28c at the positions illustrated in FIG. 3 while reducing the size of the entire light-emitting device 20 in a plan view. With the center of the light-emitting element 24 coinciding with the center of the second surface 251b, it is possible to emit light in a uniform direction with respect to the center of the second surface 251b, and it is thus possible to reduce uneven luminance distribution. When the light-emitting device 20 includes a plurality of the light-emitting elements 24, the center of the light-emitting element 24 refers to the center of the entire outer shape of the plurality of light-emitting elements 24.

Hereinafter, each of the members included in the light-emitting device 20 will be described in detail.

[Leads 22a, 22b]

The lead 22a and the lead 22b are members each electrically connected to either the negative electrode or the positive electrode of a pair of electrodes of the light-emitting elements 24a and 24b, in order to supply electricity to the light-emitting elements 24a and 24b. As a material of the lead 22a and the lead 22b, for example, a metal such as copper, aluminum, gold, silver, iron, nickel, an alloy thereof, phosphor bronze, or iron-containing copper can be used. The lead 22a and the lead 22b can be formed into a predetermined shape by pressing such as rolling, punching, or extrusion, etching such as wet or dry etching, or a combination thereof. As a material of the lead 22a and the lead 22b, it is preferable to use copper having high heat dissipation properties. Note that, the lead 22a and the lead 22b may have a single-layer structure or a layered structure.

In order to improve reflectance, a metal plating of silver, aluminum, copper, gold, or the like having a single-layer or layered structure may be applied to portions or the entire surfaces of the lead 22a and the lead 22b. Note that, when a metal layer containing silver is formed on the outermost surfaces of the lead 22a and the lead 22b, a protective film of silicon oxide or the like is preferably provided on a surface of the metal layer containing silver. This can reduce the possibility that the metal layer containing silver will be discolored by, for example, sulfur components in the atmosphere. Examples of a method for forming the protective film include a known method such as vacuum processing including sputtering, an atomic layer deposition (ALD) method, and the like. As the material for the protective film, silicon oxide or aluminum oxide can be used, for example.

As illustrated in FIG. 4, it is preferable that grooves 21y are provided in the upper surfaces of the leads 22a and 22b. Each of the grooves 21y is recessed downward from the upper surfaces of the leads 22a and 22b. The grooves 21y can be formed by etching, the above-described pressing, or the like. The grooves 21y may be disposed around the light-emitting elements 24a and 24b in a plan view, or may be disposed elsewhere. In the example illustrated in FIG. 4, a portion of the wall portion 23A is disposed in the grooves 21y. Accordingly, the contact area between the wall portion 23A and each of the leads 22a and 22b increases, which improves the adhesion between the wall portion 23A and each of the leads 22a and 22b.

When the leads 22a and 22b are exposed from the wall portion 23A at the lower surface of the light-emitting device 20 as illustrated in FIG. 5, heat from the light-emitting device 20 is easily transferred to a substrate on which the light-emitting device 20 is mounted via the leads 22a and 22b. Thus, heat dissipation of the light-emitting device 20 can be improved. Further, the lower surfaces of the leads 22a and 22b exposed from the wall portion 23A can be used as external terminal portions for electrical connection to the substrate. The light-emitting device 20 may include three or more leads.

### [Wall Portion 23A, Holding Portion 23B]

The wall portion 23A is a portion that covers a part of the upper surface and the outer lateral surfaces of each of the lead 22a and the lead 22b in the support body 21. A part of each of the lead 22a and the lead 22b may or may not be exposed from the outer lateral surface 232 of the wall portion 23A. The holding portion 23B is a portion that connects the inner lateral surfaces, of the lead 22a and the lead 22b, that face each other, in the support body 21. The upper surface of the holding portion 23B and the upper surfaces of the leads 22a and 22b may be coplanar with each other. The holding portion 23B constitutes the main surface 21a of the support body 21 together with the part of the upper surface of each of the leads 22a and 22b. In the example illustrated in FIG. 1 to FIG. 3, the wall portion 23A and the holding portion 23B are, for example, integrally connected and made of the same material.

In the example illustrated in FIG. 2, the first inclined surfaces 231a of the wall portion 23A are shown as straight lines in a cross-sectional view, but this is not limited thereto. The first inclined surfaces 231a may be curved lines that are curved to rise in a direction away from the leads 22a and 22b, or to be recessed in a direction toward the leads 22a and 22b.

The inner lateral surfaces 233 of the wall portion 23A may be inclined surfaces inclined with respect to the upper surfaces of the lead 22a and the lead 22b, or may be perpendicular surfaces perpendicular to the upper surfaces of the lead 22a and the lead 22b. In the example illustrated in FIG. 2, the inner lateral surfaces 233 of the wall portion 23A are inclined surfaces that are inclined outward with increasing distance upward from the upper surfaces of the lead 22a and the lead 22b. Accordingly, light from the light-emitting elements 24a and 24b is more likely to be reflected upward.

For example, a resin containing a light scattering material can be used for the wall portion 23A and the holding portion 23B. Accordingly, light from the light-emitting element 24 can be reflected toward the light-transmissive member 25, and insulation between the lead 22a and the lead 22b can be ensured. Examples of the resin include a known material such as a thermosetting resin or a thermoplastic resin. Examples of the thermoplastic resin include a polyphthalamide resin, a polybutylene terephthalate (PBT), and an unsaturated polyester. Examples of the thermosetting resin include an epoxy resin, a modified epoxy resin, a silicone resin, and a modified silicone resin. A thermosetting resin such as an epoxy resin or a silicone resin, which has good heat resistance and light resistance, is preferably used as the material for the wall portion 23A and the holding portion 23B.

As the light scattering material, a material that hardly absorbs light from the light-emitting elements 24a and 24b and has a refractive index greatly different from that of the resin can be used. Examples of such a light scattering material include titanium oxide, zinc oxide, silicon oxide, zirconium oxide, aluminum oxide, and aluminum nitride. The content of the light scattering material can be in a range from 10 wt. % to 90 wt. % with respect to the resin, for example.

In the example illustrated in FIG. 3, the shape defined by the lower ends of the inner lateral surfaces 233 of the wall portion 23A in a plan view is a rectangular shape with curved corners. That is, in a plan view, the shape of the main surface 21a is a rectangular shape with curved corners. Further, in a plan view, the shape defined by the upper ends of the inner lateral surfaces 233 of the wall portion 23A is a rectangular shape. Note that the shape defined by the lower ends of the inner lateral surfaces 233 of the wall portion 23A (i.e., the shape of the main surface 21a) and the shape defined by the upper ends of the inner lateral surfaces 233 of the wall portion 23A in a plan view are not limited to the rectangular shape with the curved corners, but may be a rectangular shape with orthogonal corners or may be a circular shape.

[Light-Emitting Elements 24a and 24b]

The light-emitting elements 24a and 24b are semiconductor elements that emit light when a voltage is applied thereto, and known semiconductor elements constituted of a nitride semiconductor and other materials can be used. Examples of the light-emitting elements 24a and 24b include an LED chip. Each of the light-emitting elements 24a and 24b includes a semiconductor layered body. The semiconductor layered body includes an n-type semiconductor layer, a p-type semiconductor layer, and a light-emitting layer disposed therebetween. The light-emitting layer may have a structure such as a double heterojunction or a single quantum well (SQW) or may have a structure with a group of light-emitting layers, such as a multiple quantum well (MQW). The emission peak wavelength of the light-emitting layer can be selected as appropriate according to the purpose. The light-emitting layer can be formed such that it can emit visible light or ultraviolet light, for example. Examples of the semiconductor layered body including such a light-emitting layer include semiconductors having any compositions represented by a chemical formula of InₓAl_{y}Ga_{1-x-y}N (0≤x, 0≤y, and x+y≤1), where composition ratios x and y are various values within respective ranges.

The semiconductor layered body may have a structure including one or more light-emitting layers between the n-type semiconductor layer and the p-type semiconductor layer or may have a structure in which the n-type semiconductor layer, the light-emitting layer, and the p-type semiconductor layer, which are layered in this order, are repeated a plurality of times. When the semiconductor layered body includes a plurality of light-emitting layers, the plurality of light-emitting layers may include light-emitting layers having different emission peak wavelengths or light-emitting layers having the same emission peak wavelength. The same emission peak wavelength also includes a case in which there is a variation within +10 nm. A combination of emission peak wavelengths between the plurality of light-emitting layers can be selected as appropriate. For example, when the semiconductor layered body includes two light-emitting layers, light-emitting layers can be selected in combination of blue light and blue light, green light and green light, red light and red light, ultraviolet light and ultraviolet light, blue light and green light, blue light and ultraviolet light, blue light and red light, or green light and red light. Each of the light-emitting layers may include a plurality of active layers having different emission peak wavelengths or may include a plurality of active layers having the same emission peak wavelength.

In the example of FIG. 3, two light-emitting elements (light-emitting elements 24a and 24b) are mounted on one light-emitting device 20. Alternatively, only one light-emitting element may be mounted on a single light-emitting device 20, or three or more light-emitting elements may be mounted on one light-emitting device 20. When a single light-emitting device 20 includes a plurality of light-emitting elements, a plurality of light-emitting elements having the same emission peak wavelength may be combined in order to improve the luminous intensity of the entire light-emitting device 20. For example, in order to improve color reproductivity, a plurality of light-emitting elements having different emission peak wavelengths may be combined to correspond to a red color, a green color, and a blue color. When the light-emitting device 20 includes the plurality of light-emitting elements, all the light-emitting elements may be connected in series, may be connected in parallel, or may be connected using a combination of series connection and parallel connection. The light-emitting element may be mounted in a face-up manner in which it is mounted with the surface on which the electrodes are formed facing upward or mounted in a flip-chip manner in which it is mounted with the surface on which the electrodes are formed facing downward.

### [Light-Transmissive Member 25]

The light-transmissive member 25 is a member that controls light distribution characteristics of the light-emitting device 20. The first light-transmissive member 26 and the second light-transmissive member 27 that constitute the light-transmissive member 25 are members that are transmissive of light from the light-emitting element 24.

### [First Light-Transmissive Member 26]

The first light-transmissive member 26 can contain a wavelength conversion material. This can facilitate adjustment in chromaticity of light to be emitted from the light-emitting device 20. In the example illustrated in FIG. 2, the first light-transmissive member 26 is a resin containing a wavelength conversion material. Examples of the resin used for the first light-transmissive member 26 include known light-transmissive resins such as a silicone resin and an epoxy resin. Among them, a silicone resin having good reliability (specifically, a phenyl silicone resin, a dimethyl silicone resin, or the like) can be suitably used. Glass may be used instead of the resin.

The wavelength conversion material contained in the first light-transmissive member 26 may be of one type or a plurality of types. The wavelength conversion material contained in the first light-transmissive member 26 may be dispersed or unevenly distributed. As the wavelength conversion material, a known phosphor can be used. The phosphor is adapted to be excited by the light emitted from the light-emitting element 24 and to emit light having a wavelength different from the wavelength of the light emitted from the light-emitting element 24. As the phosphor, an yttrium aluminum garnet-based phosphor (for example, (Y,Gd)₃(Al,Ga)O₁₂:Ce), a lutetium aluminum garnet-based phosphor (for example, Lu₃(Al,Ga)₅O₁₂:Ce), a terbium aluminum garnet-based phosphor (for example, Tb₃(Al,Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba,Sr,Ca,Mg)₂SiO₄:Eu), an oxynitride-based phosphor such as a β-SiAlON-based phosphor (for example, (Si,Al)₃(O,N)₄:Eu) or an α-SiAlON-based phosphor (for example, Ca(Si,Al)₁₂(O,N)₁₆:Eu), a nitride-based phosphor such as an LSN-based phosphor (for example, (La, Y)₃Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), or an SCASN-based phosphor (for example, (Sr,Ca)AlSiN₃:Eu), a fluoride-based phosphor such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), or an MGF-based phosphor (for example, 3.5MgO·0.5MgF₂·GeO₂:Mn), a quantum dot having a perovskite structure (for example, (Cs,FA,MA)(Pb,Sn)(F,Cl,Br,I)₃, where FA and MA represent formamidinium and methylammonium, respectively), a group II-VI quantum dot (for example, CdSe), a III-V quantum dot (for example, InP), a quantum dot having a chalcopyrite structure (for example, (Ag,Cu)(In,Ga)(S,Se)₂), or the like can be used.

### [Second Light-Transmissive Member 27]

In the example of FIG. 2, the second light-transmissive member 27 covers the upper surface 231 of the wall portion 23A including the first inclined surfaces 231a, and the upper surface 26a of the first light-transmissive member 26. In the example of FIG. 2, the second light-transmissive member 27 covers the upper surfaces of the light-emitting elements 24a and 24b via the first light-transmissive member 26, but is not limited thereto. The second light-transmissive member 27 may be in contact with the upper surfaces of the light-emitting elements 24a and 24b and may cover the light-emitting elements 24a and 24b. That is, the light-transmissive member 25 may be constituted by only the second light-transmissive member 27. In the case in which the light-transmissive member 25 is constituted by only the second light-transmissive member 27, for example, the wavelength conversion material is unevenly distributed so as to be only in a region inside the recessed portion 21x.

In the example illustrated in FIG. 2, a second surface of the second light-transmissive member 27, that is, the second surface 251b of the light-transmissive member 25 includes a flat surface 251b1 located above the light-emitting element 24, a second inclined surface 251b2, and a curved surface 251b3 connecting the second inclined surface 251b2 and the flat surface 251b1. In a plan view, the curved surface 251b3 is located outward of the flat surface 251b1, and the second inclined surface 251b2 is located outward of the curved surface 251b3.

The flat surface 251b1 is, for example, parallel to the main surface 21a. Light emitted from the flat surface 251b1 has a higher luminance than that of light emitted from the second inclined surface 251b2 and that of light emitted from the curved surface 251b3, and thus there is a high-luminance region, corresponding to the light emitted from the flat surface 251b1, in the luminance distribution. The high-luminance region corresponds to the size and shape of the flat surface 251b1 in a plan view. Accordingly, the size and shape of the high-luminance region can be changed by changing the size and shape of the flat surface 251b1 in a plan view. In the example illustrated in FIG. 1, the shape of the flat surface 251b1 in a plan view is a circular shape, so that a circular high-luminance region is obtained. Further, in the example illustrated in FIG. 2, the flat surface 251b1 is located inside the recessed portion 21x in a plan view.

The second inclined surface 251b2 is, for example, a flat surface at an angle of 8 degrees or more and 16 degrees or less with respect to the line normal to the main surface 21a. The closer to 0 degrees the angle between the second inclined surface 251b2 and the normal line of the main surface 21a is, that is, the closer to being a surface perpendicular to the main surface 21a the second inclined surface 251b2 is, the larger the amount of light that is totally reflected. Thus, the second inclined surface 251b2 at such an angle can contribute to the narrowing of the light distribution.

The curved surface 251b3 has, for example, a curvature radius of 0.1 mm or more and 0.9 mm or less. With the second surface 251b including the curved surface 251b3, the light having been emitted from the light-emitting element 24 and having reached the curved surface 251b3 can be refracted directly upward, which can contribute to the narrowing of the light distribution.

The curvature radius of the third surface 251c is preferably smaller than the curvature radius of the curved surface 251b3. By reducing the curvature radius of the third surface 251c, the second inclined surface 251b2 can be made longer. Accordingly, it is possible to reduce the light reflected by the third surface 251c, increase the light emitted from the second inclined surface 251b2 to the outside, and improve the light extraction efficiency.

The distance in the Z direction between the first surface 251a and the flat surface 251b1 is, for example, 0.8 mm or more and 1.2 mm or less. The distance in the Z direction between the first surface 251a and the flat surface 251b1 is, for example, ½ or more of the height of the entire light-emitting device 20 in the Z direction.

The shape of the second surface 251b is not limited to that of the example illustrated in FIG. 2. For example, instead of the curved surface 251b3, an inclined surface whose inclination angle with respect to the normal line of the main surface 21a is larger than that of the second inclined surface 251b2 may be provided.

In another example, the second surface 251b does not include the curved surface 251b3, and the second inclined surface 251b2 and the flat surface 251b1 may be directly connected to each other. In this case, the second inclined surface 251b2 may be a curved surface that is convex outward, instead of being a flat surface. Further, the second surface 251b may include a curved surface that is convex upward instead of the flat surface 251b1.

In the example illustrated in FIG. 2, a resin can be used for the second light-transmissive member 27. As the resin used for the second light-transmissive member 27, the resin described above for the first light-transmissive member 26 can be used. The resin used for the second light-transmissive member 27 may be the same material as the resin used for the first light-transmissive member 26, or may be a material different from that.

In the example illustrated in FIG. 2, the second light-transmissive member 27 does not contain the above-described wavelength conversion material and light scattering material. Accordingly, it is possible to reduce spread, over a wide range, of the light emitted from the second light-transmissive member 27, which contributes to the narrowing of the light distribution. Note that the second light-transmissive member 27 may contain the wavelength conversion material and/or the light scattering material to the extent that the wavelength conversion material and/or the light scattering material do not interfere with the narrowing of the light distribution.

### Modified Examples of First Embodiment

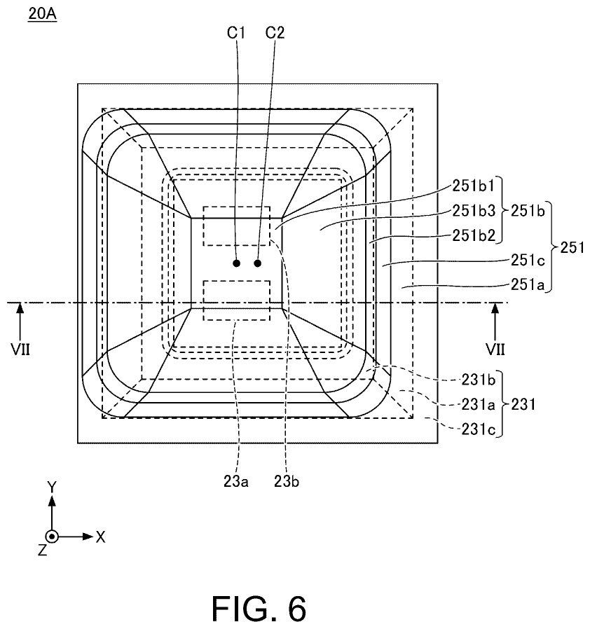

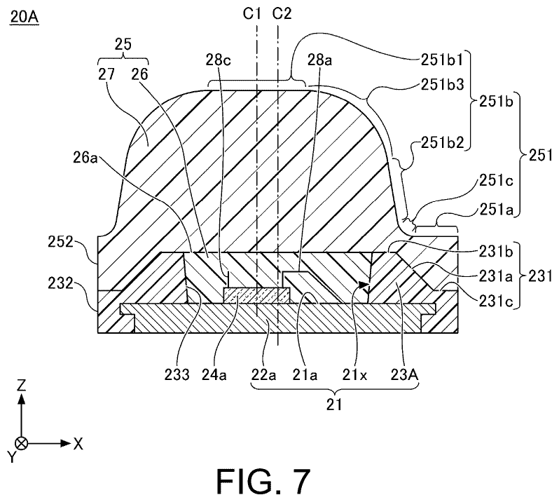

FIG. 6 is a schematic top view exemplifying a light-emitting device according to a first modified example of the first embodiment. FIG. 7 is a schematic cross-sectional view taken along line VII-VII in FIG. 6. As illustrated in FIG. 6, a light-emitting device 20A is different from the light-emitting device 20 in the outer shape of the second surface 251b (i.e., the outer shape of the second inclined surface 251b2) and the outer shape of the third surface 251c. In the light-emitting device 20, the outer shapes of the second surface 251b and the third surface 251c in a plan view are circular shapes. On the other hand, in the light-emitting device 20A, the outer shapes of the second surface 251b and the third surface 251c in a plan view are rectangular shapes with curved corners in a plan view. In the light-emitting device 20A, as in the light-emitting device 20, light having a narrow light distribution can be emitted from the second surface 251b of the light-transmissive member 25.

In the example illustrated in FIG. 6, in the light-emitting device 20A, the shape of the flat surface 251b1 of the second surface 251b in a plan view is a rectangular shape. Therefore, the high-luminance region corresponding to the light emitted from the flat surface 251b1 of the second surface 251b has a rectangular shape in a plan view. In a case in which light-emitting devices are arranged in a matrix on a substrate for a planar light source, when the light-emitting devices 20A, in each of which the shape of the high-luminance region is the rectangular shape in a plan view, are used, luminance unevenness between the light-emitting devices 20A can be reduced.

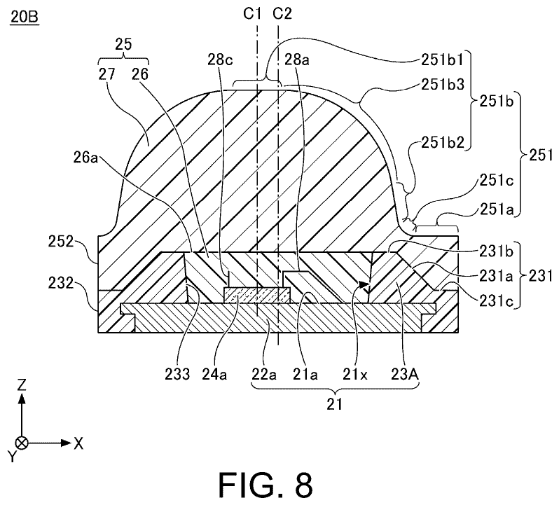

FIG. 8 is a schematic cross-sectional view exemplifying a light-emitting device according to a second modified example of the first embodiment. As illustrated in FIG. 8, a light-emitting device 20B is different from the light-emitting device 20 in the curvature radius of the curved surface 251b3 in a cross-sectional view. In the light-emitting device 20B, the curvature radius of the curved surface 251b3 in a cross-sectional view is larger than the curvature radius of the curved surface 251b3 in the light-emitting device 20.

In the light-emitting device 20B, as in the light-emitting device 20, light having a narrow light distribution can be emitted from the second surface 251b of the light-transmissive member 25.

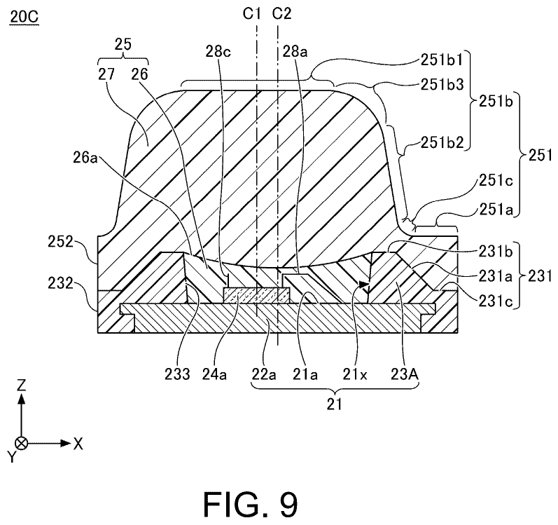

FIG. 9 is a schematic cross-sectional view exemplifying a light-emitting device according to a third modified example of the first embodiment. As illustrated in FIG. 9, a light-emitting device 20C is different from the light-emitting device 20 in the shape of the upper surface 26a of the first light-transmissive member 26. In the light-emitting device 20, the upper surface 26a of the first light-transmissive member 26 is flat. On the other hand, in the light-emitting device 20C, the upper surface 26a of the first light-transmissive member 26 has a recessed shape.

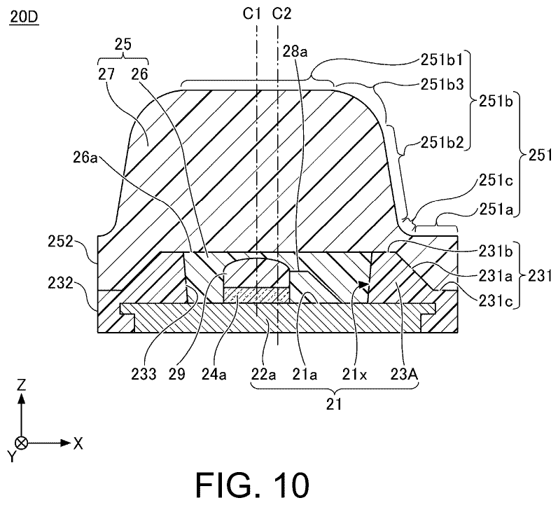

In the light-emitting device 20C, as in the light-emitting device 20, light having a narrow light distribution can be emitted from the second surface 251b of the light-transmissive member 25. Further, with the recessed shape of the upper surface 26a of the first light-transmissive member 26, when the refractive index of the first light-transmissive member 26 is larger than the refractive index of the second light-transmissive member 27, light having traveled from the first light-transmissive member 26 and entered the second light-transmissive member 27 is refracted toward the center “C1” at the interface between the first light-transmissive member 26 and the second light-transmissive member 27, and this can contribute to the narrowing of the light distribution. FIG. 10 is a schematic cross-sectional view exemplifying a light-emitting device according to a fourth modified example of the first embodiment. As illustrated in FIG. 10, a light-emitting device 20D is different from the light-emitting device 20 in that the light-emitting device 20D includes a third light-transmissive member 29. In the light-emitting device 20D, the third light-transmissive member 29 containing a wavelength conversion material is disposed on the light-emitting element 24, and the third light-transmissive member 29 is covered with the first light-transmissive member 26. In the light-emitting device 20D, as in the light-emitting device 20, light having a narrow light distribution can be emitted from the second surface 251b of the light-transmissive member 25.

The first light-transmissive member 26 may or may not contain the wavelength conversion material. When the first light-transmissive member 26 contains the wavelength conversion material, the wavelength conversion material contained in the third light-transmissive member 29 may be the same material as the wavelength conversion material contained in the first light-transmissive member 26, or may be a material different from that. Further, when the wavelength conversion material contained in the third light-transmissive member 29 is the same material as the wavelength conversion material contained in the first light-transmissive member 26, the concentration of the wavelength conversion material contained in the third light-transmissive member 29 can be higher than the concentration of the wavelength conversion material contained in the first light-transmissive member 26. The light emitted from the upper surface of the light-emitting element 24 travels a shorter distance to reach the upper surface of the first light-transmissive member 26 than the light emitted from the lateral surface of the light-emitting element 24, so that a smaller amount of light of the light emitted from the upper surface of the light-emitting element 24 is wavelength-converted. Thus, the light emitted from the upper surface of the first light-transmissive member 26 may have color unevenness between a portion directly above the light-emitting element 24 and a portion other than the portion directly above the light-emitting element 24. In contrast, when the above-described configuration is adopted, it is possible to increase the amount of light to be wavelength-converted of the light emitted from the upper surface of the light-emitting element 24. Thus, the color unevenness can be reduced.

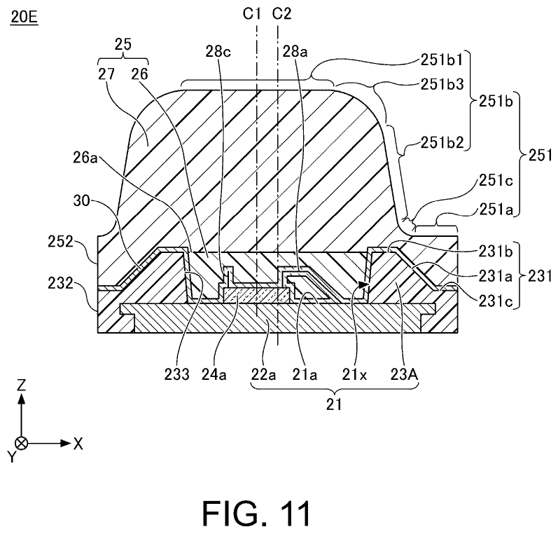

FIG. 11 is a schematic cross-sectional view exemplifying a light-emitting device according to a fifth modified example of the first embodiment. As illustrated in FIG. 11, a light-emitting device 20E is different from the light-emitting device 20 in that the light-emitting device 20E includes a protective film 30 disposed between the wall portion 23A and the light-transmissive member 25.

The protective film 30 is disposed so as to cover at least the upper surface 231 of the wall portion 23A. In the example illustrated in FIG. 11, the protective film 30 may cover the inner lateral surfaces 233 of the wall portion 23A, the main surface 21a of the recessed portion 21x, and the light-emitting element 24a, in addition to the upper surface 231 of the wall portion 23A. Examples of the material for the protective film 30 include silicon oxide. When a protective film is disposed on the outermost surfaces of the lead 22a and the lead 22b, for example, the protective film 30 can be formed by the same film-forming method using the same material as that of the protective film disposed on the outermost surfaces of the lead 22a and the lead 22b.

In the light-emitting device 20E, as in the light-emitting device 20, light having a narrow light distribution can be emitted from the second surface 251b of the light-transmissive member 25. Further, with the protective film 30 disposed between the wall portion 23A and the light-transmissive member 25, it is possible to improve adhesion between the wall portion 23A and the light-transmissive member 25.

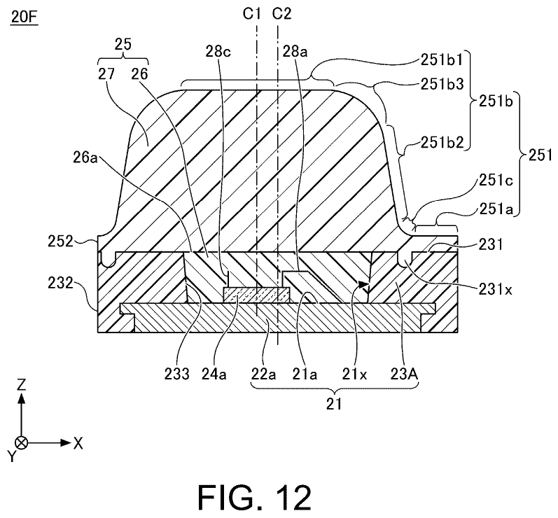

FIG. 12 is a schematic cross-sectional view exemplifying a light-emitting device according to a sixth modified example of the first embodiment. As illustrated in FIG. 12, a light-emitting device 20F is different from the light-emitting device 20 in that the light-emitting device 20F includes a recessed portion 231x that opens to the upper surface 231 of the wall portion 23A. In the light-emitting device 20F, the entire upper surface 231 of the wall portion 23A is a flat surface and does not have an inclined surface. In the example illustrated in FIG. 12, the upper surface 231 of the wall portion 23A is parallel to the main surface 21a of the support body 21.

The third surface 251c is located above the recessed portion 231x. The recessed portion 231x can be provided, for example, in a rectangular frame shape surrounding the recessed portion 21x in a plan view. The second light-transmissive member 27 is disposed in the recessed portion 231x.

In the light-emitting device 20F, with the recessed portion 231x opening to the upper surface 231 of the wall portion 23A, the light having been emitted from the light-emitting element 24 and having reached the third surface 251c is reflected by the third surface 251c and travels toward the recessed portion 231x. The light having reached the recessed portion 231x is reflected in the recessed portion 231x, and it is thus possible to reduce the light traveling from the recessed portion 231x to the first surface 251a side and/or the lateral surface 252 side of the light-transmissive member 25. Further, a part of the light reflected in the recessed portion 231x can travel to the flat surface 251b1 side of the second surface 251b, so that it is possible to increase the light extraction efficiency of the light emitted from the second surface 251b. Therefore, as in the light-emitting device 20, light with a narrow light distribution can be emitted from the second surface 251b of the light-transmissive member 25.

The shape of the recessed portion 231x in a cross-sectional view is, for example, a shape defined by two lateral surfaces and a main surface connecting the lower ends of the two lateral surfaces, or a shape defined by only the two lateral surfaces. In a cross-sectional view, the lateral surface defining the recessed portion 231x may be a surface perpendicular to the upper surface 231, or may be an inclined surface with respect to the upper surface 231. Further, the lateral surface may be constituted by only a curved surface or may be constituted by a surface including a curved surface. The two lateral surfaces may have the same shape or different shapes in a cross-sectional view. The main surface defining the recessed portion 231x may be a flat surface parallel to the upper surface 231 or a curved surface recessed toward the lead 22a side.

In the example illustrated in FIG. 12, the cross-sectional shape of the recessed portion 231x is a shape defined by lateral surfaces perpendicular to the upper surface 231 and a main surface recessed toward the leads 22a and 22b side (i.e., a U shape). In a cross-sectional view, the distance in the X direction between the upper ends of the lateral surfaces defining the recessed portion 231x (i.e., the width of the recessed portion 231x) is preferably in a range from 1 time to 2 times the width of the third surface 251c in the X direction, in consideration of narrowing of the light distribution and the strength of the resin member 23. Further, in consideration of the strength of the resin member 23, the depth of the recessed portion 231x is preferably equal to or less than half of the thickness of the wall portion 23A in a cross-sectional view.

### [Planar Light Source 1]

The above-described light-emitting device can be disposed on a substrate to form a planar light source. Here, the planar light source will be described using the light-emitting device 20 as an example. However, the light-emitting devices 20A to 20F described above may be used instead of the light-emitting device 20.

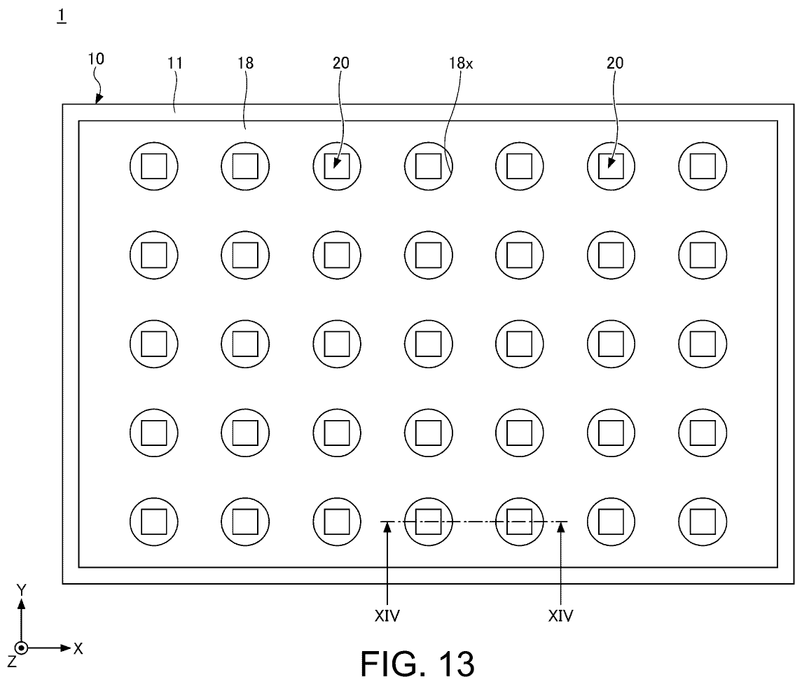

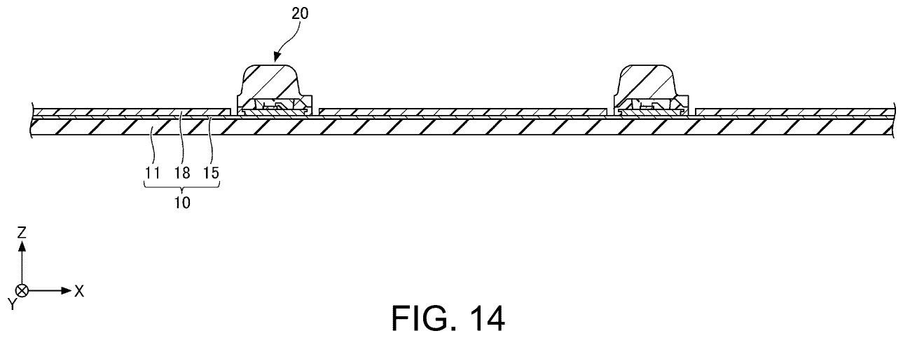

FIG. 13 is a schematic top view illustrating a planar light source according to the first embodiment. FIG. 14 is a schematic cross-sectional view taken along line XIV-XIV illustrated in FIG. 13.

In the example illustrated in FIG. 13 and FIG. 14, a planar light source 1 includes a substrate 10 and a plurality of light-emitting devices 20 disposed two-dimensionally. In the example illustrated in FIG. 13, in the planar light source 1, the light-emitting devices 20 are arranged in a matrix on the substrate 10. The planar light source 1 includes the plurality of light-emitting devices 20 having narrow light distribution characteristics, so that narrow light distribution characteristics can also be realized by the entire planar light source 1. The light-emitting devices are not limited to being arranged in the matrix on the substrate, but may be arranged in a staggered manner. The members included in the planar light source 1 will be described in detail below.

### [Substrate 10]

The substrate 10 is a member on which the plurality of light-emitting devices 20 are mounted. In the example illustrated in FIG. 13 and FIG. 14, the substrate 10 includes a base member 11, a conductor wiring member 15, and a covering member 18. The conductor wiring member 15 is a member for supplying power to the light-emitting device 20, and is disposed on the upper surface of the base member 11. The covering member 18 covers, for example, a part of a region, of the conductor wiring member 15, that is not electrically connected to the light-emitting device 20. The covering member 18 includes an opening portion 18x, and the light-emitting device 20 is disposed in the opening portion 18x.

Any material can be used as a material of the base member 11 as long as it can insulate at least a pair of conductor wiring members 15 from each other, and examples of the material include ceramics, resins, and composite materials. Examples of the resins include a phenol resin, an epoxy resin, a polyimide resin, a BT resin, polyphthalamide (PPA), and polyethylene terephthalate (PET). Examples of the composite materials include a mixture of any one of the above-mentioned resins and an inorganic filler of glass fiber, silicon oxide, titanium oxide, aluminum oxide, or the like, a glass fiber reinforced resin (glass epoxy), and a metal substrate in which a metal member is coated with an insulating layer.

The thickness of the base member 11 can be appropriately selected. The base member 11 can be a flexible substrate that can be manufactured in roll-to-roll processing or a rigid substrate. The rigid substrate may be a bendable thin rigid substrate.

Any appropriate material may be used as the conductor wiring member 15 as long as it is a conductive member, and a material commonly used as a wiring layer of a circuit board or the like can be used. As the material of the conductor wiring member 15, for example, copper can be used.

The covering member 18 has an insulating property. Examples of the material of the covering member 18 include the same materials as those exemplified as the material of the base member 11. As the covering member 18, any of the above-mentioned resins containing a white light reflective filler such as titanium oxide, aluminum oxide, or silicon oxide and/or a large number of air bubbles can be used. Accordingly, the light emitted from the light-emitting device 20 is reflected by the covering member 18, and thus the light extraction efficiency of the planar light source 1 can be improved.

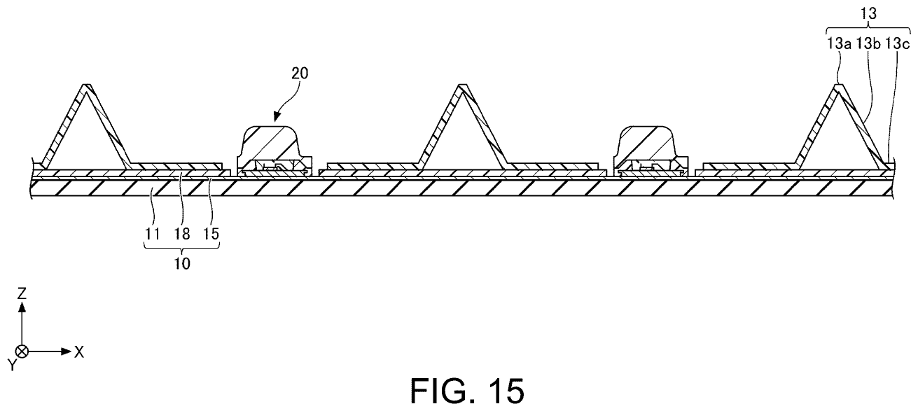

FIG. 15 is a schematic partial cross-sectional view illustrating the planar light source including a demarcating member. As illustrated in FIG. 15, the planar light source 1 can include a demarcating member 13. The demarcating member 13 can reflect upward the light that has been emitted to the outside from the second inclined surface 251b2 of the second light-transmissive member 27 of the light-emitting device 20 and that has reached the demarcating member 13.

The demarcating member 13 is disposed on a side of the substrate 10 being the same as a side at which the light-emitting devices 20 is located. The demarcating member 13 includes a top portion 13a in a lattice shape in a plan view, a wall portion 13b surrounding each of the light-emitting devices 20 in a plan view, and a bottom portion 13c connected to the lower end of the wall portion 13b, and further includes a plurality of regions surrounding the light-emitting device 20. The wall portion 13b of the demarcating member 13, for example, extends from the top portion 13a toward the substrate 10 such that, in a cross-sectional view, the width in the region surrounded by the opposing portions of the wall portion 13b is reduced toward the substrate 10 side. In the example illustrated in FIG. 15, a single light-emitting device 20 is disposed in a single section surrounded by a corresponding portion of the wall portion 13b. However, two or more of the light-emitting devices 20 may be disposed in a single section.

The demarcating member 13 preferably has light reflectivity. Accordingly, the light emitted from the light-emitting device 20 can be efficiently reflected upward by the demarcating member 13. In this case, the demarcating member 13 can be molded using a resin containing a light reflective filler such as titanium oxide, aluminum oxide, or silicon oxide, and/or a large number of air bubbles, or can be molded using a resin containing no reflective material and subsequently provided with a reflective material on the surface thereof. When the demarcating member 13 contains a resin containing a large number of air bubbles, light is reflected at the interface between the air bubbles and the resin. Examples of the resin used for the demarcating member 13 include thermoplastic resins such as an acrylic resin, a polycarbonate resin, a cyclic polyolefin resin, polyethylene terephthalate, polyethylene naphthalate, and polyester, and thermosetting resins such as an epoxy resin and a silicone resin. The demarcating member 13 is preferably set such that the reflectance thereof with respect to the light emitted from the light-emitting device 20 is 70% or more.

In the above-described example, the planar light source 1 includes the substrate 10, but is not limited thereto. The substrate 10 is provided as necessary and can be omitted. For example, in the planar light source 1, it is possible to employ a structure in which the plurality of light-emitting devices 20 are held by an integral light-transmissive resin or the like.

Further, the planar light source 1 may include an optical member disposed above the light-emitting devices 20 with the demarcating member 13 disposed therebetween. The optical member is, for example, a light-diffusive sheet. When the planar light source 1 includes a light-diffusive sheet, it is possible to improve uniformity of light extracted from the planar light source 1 to the outside. The planar light source 1 can further include, above the light-diffusive sheet, at least one selected from the group consisting of a first prism sheet, a second prism sheet, and a polarizing sheet. When the planar light source 1 includes one or more of these optical members, the uniformity of light can be further improved.

### Second Embodiment

In a second embodiment, an example of a liquid crystal display device using the planar light source 1 as a backlight source is described.

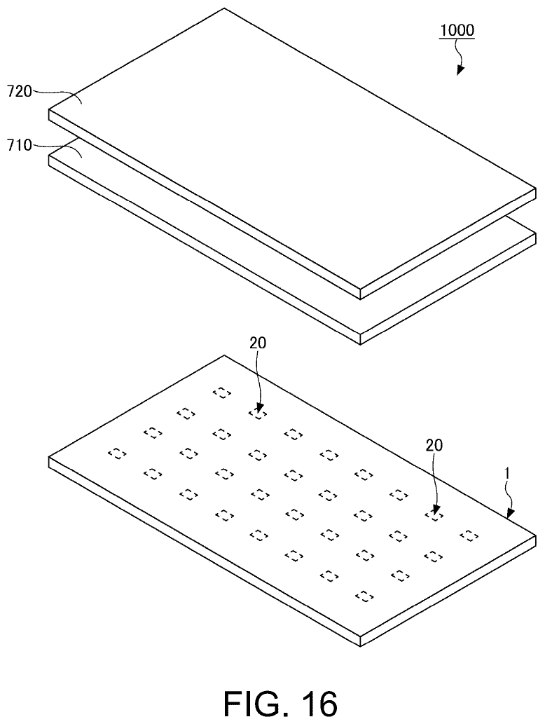

FIG. 16 is a configuration view illustrating a liquid crystal display device according to the second embodiment. As illustrated in FIG. 16, a liquid crystal display device 1000 includes, in order from the top, a liquid crystal panel 720, an optical member 710, and the planar light source 1. The planar light source 1 can include the light-emitting devices 20 and an optical member located above the light-emitting devices 20. In the optical member, for example, a diffusion plate, a first prism sheet, a second prism sheet, and a reflective polarizing sheet (DBEF) are layered in this order from the light-emitting devices 20 side.

The liquid crystal display device 1000 is a so-called direct-lit liquid crystal display device in which the planar light source 1 is layered below the liquid crystal panel 720. In the liquid crystal display device 1000, the liquid crystal panel 720 is irradiated with the light emitted from the planar light source 1.

From the viewpoint of thinning the planar light source 1, the thickness of the planar light source 1 can be equal to or less than 15 mm. This can reduce the thickness of the planar light source 1, leading to a reduction in the thickness of the liquid crystal display device 1000.

The planar light source 1 can be used as a backlight for the liquid crystal display device 1000 for televisions, tablets, smartphones, smart watches, head-up displays, digital signage, bulletin boards, and the like. In addition, the planar light source 1 can also be used as a light source for lighting, and can also be used for emergency lights, line lighting, various illuminations, vehicle instrument panels, and the like.

Preferred embodiments and the like have been described above in detail. However, the present disclosure is not limited to the above-described embodiments and the like, and various modifications and substitutions can be made to the above-described embodiments and the like without departing from the scope described in the claims.

What is claimed is:

1. A light-emitting device comprising:
a support body, comprising:
a wall portion,
a main surface surrounded by the wall portion, and
a recessed portion defined by the wall portion and the main surface;
a light-emitting element, mounted on the main surface; and
a light-transmissive member, disposed on the wall portion and the light-emitting element,
wherein
an upper surface of the light-transmissive member comprises:
a first surface,
a second surface, surrounded by the first surface in a plan view and protruding upward relative to the first surface in a cross-sectional view, and
a third surface, having a curved shape and connecting the first surface and the second surface in a cross-sectional view,
an upper surface of the wall portion comprises: a first inclined surface, inclined with respect to the main surface, and
the third surface is located above the first inclined surface.

2. The light-emitting device according to claim 1, wherein
the second surface comprises a flat surface, being located above the light-emitting element.

3. The light-emitting device according to claim 2, wherein
the second surface comprises:
a second inclined surface; and
a curved surface, connecting the second inclined surface and the flat surface.

4. The light-emitting device according to claim 1, wherein
the second surface has a circular shape in a plan view.

5. The light-emitting device according to claim 1, wherein
the second surface has a rectangular shape with a curved corner in a plan view.

6. The light-emitting device according to claim 1, wherein
in a plan view, a center of the light-emitting element is different from a center of the main surface and coincides with a center of the second surface.

7. The light-emitting device according to claim 1, wherein
the light-transmissive member comprises:
a first light-transmissive member, disposed in the recessed portion and containing a wavelength conversion material; and
a second light-transmissive member, disposed on the first light-transmissive member and the wall portion and not containing the wavelength conversion material.

8. The light-emitting device according to claim 7, wherein
an upper surface of the first light-transmissive member has a recessed shape.

9. The light-emitting device according to claim 7, further comprising:
a third light-transmissive member, containing the wavelength conversion material and disposed on the light-emitting element,
wherein
the third light-transmissive member is covered with the first light-transmissive member.

10. The light-emitting device according to claim 1, further comprising:
a protective film, disposed between the wall portion and the light-transmissive member.

11. A planar light source comprising:
a substrate; and
a plurality of the light-emitting devices according to claim 1, being disposed on the substrate and arranged two-dimensionally.

12. A liquid crystal display device comprising:
a liquid crystal panel; and
the planar light source according to claim 11 as a backlight light source;
wherein
the planar light source further comprises an optical member, being disposed above the plurality of the light-emitting devices.
